(19) United States
(12) Patent Application Publication
(10) Pub. No.: US 2014/0365148 A1
(43) Pub. Date: Dec. 11, 2014

(54) Methods And Systems For Test Power Analysis

(71) Applicant: University of Connecticut, Farmington, CT (US)

(72) Inventors: Mohammad Tehranipoor, Mansfield, CT (US); Wei Zhao, San Jose, CA (US)

(21) Appl. No.: 14/242,183

(22) Filed: Apr. 1, 2014

Related U.S. Application Data
(60) Provisional application No. 61/807,106, filed on Apr. 1, 2013.

(51) Int. Cl. G01R 21/133; G01R 31/28

(52) U.S. Cl. CPC G01R 21/133; G01R 31/2851
USPC 702/60

(57) ABSTRACT

Provided are methods and systems for test power analysis. An example method can comprise creating a test pattern from topology data of an integrated circuit and creating a map from the topology data of the integrated circuit. A test power analysis of the integrated circuit can be performed using the created test pattern and the map. In an aspect, an example method can comprise obtaining transition information via monitoring transitions of a plurality of test cycles in a test session of an integrated circuit. Simulation data can be obtained via simulating a plurality of functions of the plurality of test cycles in the test session of the integrated circuit using the transition information. A test power analysis of the plurality of test cycles in the test session of the integrated circuit can be performed using the obtained simulation data.

### CROSS REFERENCE TO RELATED PATENT APPLICATION

This application claims priority to U.S. Provisional Application No. 61/807,106 filed Apr. 1, 2013, herein incorporated by reference in its entirety.

### GOVERNMENT SUPPORT CLAUSE

This invention was made with government support under CCF-0811632 awarded by the National Science Foundation. The government has certain rights in the invention.

### BACKGROUND

In integrated circuit (IC) manufacturing, ICs are usually tested to screen for defective ICs by automated methods. Such testing can use much more power than the ICs are designed to handle, leading to burn out of the ICs. Additionally, testing can cost up to 50% of the cost of manufacturing the ICs. Power consumption has become a critical concern in testing ICs, and peak power/current detection for testing is needed to help identify hazardous vectors and ensure both power safety and test power integrity. Test power analysis (TPA) has its own characteristics: (1) TPA is vector-based, (2) TPA requires a large number of timing windows to be analyzed, and (3) TPA should be layout-aware to understand current distribution among power mesh network. There are no existing tools for TPA that meet all the above criteria. These and other shortcomings are addressed in the present disclosure.

### SUMMARY

It is to be understood that both the following general description and the following detailed description are exemplary and explanatory only and are not restrictive, as claimed. Provided are methods and systems for test power analysis. An example method can comprise creating a test pattern from topology data of an integrated circuit and creating a map from the topology data of the integrated circuit. A test power analysis of the integrated circuit can be performed using the created test pattern and the map.

In an aspect, an example method can comprise obtaining transition information via monitoring transitions of a plurality of test cycles in a test session of an integrated circuit. Simulation data can be obtained via simulating a plurality of functions of the plurality of test cycles in the test session of the integrated circuit using the transition information. A test power analysis of the plurality of test cycles in the test session of the integrated circuit can be performed using the obtained simulation data.

Additional advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

### BRIEF DESCRIPTION OF THE DRAWINGS

The accompanying drawings, which are incorporated in and constitute a part of this specification, illustrate embodiments and together with the description, serve to explain the principles of the methods and systems:

FIG. 1 illustrates an infrastructure for performing power analysis for test patterns;

FIG. 2 illustrates load capacitance calculation;

FIG. 3A illustrates an example of the power straps being used to partition a layout into a plurality of regions;

FIG. 3B illustrates an example of a WSA_{A} matrix;

FIG. 4A illustrates side view of standard cells, power bump cells and metal 8 to 11 of a power network structure for an industry circuit design;

FIG. 4B illustrates top view of standard cells, power bump cells and metal 8 to 11 of a power network structure for an industry circuit design;

FIG. 5A illustrates a 7×3 partitioning based on power bumps location;

FIG. 5B illustrates a 13×8 partitioning based on power bumps location;

FIG. 6 illustrates an example PDN structure;

FIG. 7 illustrates a resistive path from one power bump to a region;

FIG. 8 illustrates RC modeling for power and ground nodes;

FIG. 9 illustrates resistance network for a 13×8 partition as in FIG. 5B;

FIG. 10 illustrates a power validation flow;

FIG. 11 is a flowchart illustrating an example method for test power analysis;

FIG. 12 is a flowchart illustrating an example method for test power analysis;

FIG. 13A illustrates net toggling rates comparison between the disclosed method and a commercial tool;

FIG. 13B illustrates scan flip-flop toggling rates comparison between the disclosed method and a commercial tool;

FIG. 14A illustrates average power comparison between the disclosed method and a commercial tool for P.S_S.1;

FIG. 14B illustrates average power comparison between the disclosed method and a commercial tool for P.5_C.1;

FIG. 15A illustrates WSA*R plots for P.4_S.290;

FIG. 15B illustrates IR-drop plot for P.4_S.290;

FIG. 15C illustrates WSA*R plots for P.2_S.273;

FIG. 15D illustrates IR-drop plot for P.2_S.273;

FIG. 15E illustrates WSA*R plots for P.9_C.1;

FIG. 15F illustrates IR-drop plot for P.9_C.1;

FIG. 16 illustrates regional WSA example for one shift cycle of a LOC pattern in an IC design;

FIG. 17A illustrates relationship between WSA and current for VSS bump (2,4);

FIG. 17B illustrates relationship between WSA and current for VDD bump (2,0);

FIG. 18A illustrates current estimation for VSS bump (2,0);

FIG. 18B illustrates a comparison between predicted I and reference I values; and

FIG. 18C illustrates predicted error of current estimation for VSS bump (2,0).

### DETAILED DESCRIPTION

Before the present methods and systems are disclosed and described, it is to be understood that the methods and systems are not limited to specific methods, specific components, or to particular configurations. It is also to be understood that the terminology used herein is for the purpose of describing particular embodiments only and is not intended to be limiting.

As used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal embodiment. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

The present methods and systems may be understood more readily by reference to the following detailed description of preferred embodiments and the Examples included therein and to the Figures and their previous and following description.

As will be appreciated by one skilled in the art, the methods and systems may take the form of an entirely hardware embodiment, an entirely software embodiment, or an embodiment combining software and hardware aspects. Furthermore, the methods and systems may take the form of a computer program product on a computer-readable storage medium having computer-readable program instructions (e.g., computer software) embodied in the storage medium. More particularly, the present methods and systems may take the form of web-implemented computer software. Any suitable computer-readable storage medium may be utilized including hard disks, CD-ROMs, optical storage devices, or magnetic storage devices.

Embodiments of the methods and systems are described below with reference to block diagrams and flowchart illustrations of methods, systems, apparatuses and computer program products. It will be understood that each block of the block diagrams and flowchart illustrations, and combinations of blocks in the block diagrams and flowchart illustrations, respectively, can be implemented by computer program instructions. These computer program instructions may be loaded onto a general purpose computer, special purpose computer, or other programmable data processing apparatus to produce a machine, such that the instructions which execute on the computer or other programmable data processing apparatus create a means for implementing the functions specified in the flowchart block or blocks.

These computer program instructions may also be stored in a computer-readable memory that can direct a computer or other programmable data processing apparatus to function in a particular manner, such that the instructions stored in the computer-readable memory produce an article of manufacture including computer-readable instructions for implementing the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

Accordingly, blocks of the block diagrams and flowchart illustrations support combinations of means for performing the specified functions, combinations of steps for performing the specified functions and program instruction means for performing the specified functions. It will also be understood that each block of the block diagrams and flowchart illustrations, and combinations of blocks in the block diagrams and flowchart illustrations, can be implemented by special purpose hardware-based computer systems that perform the specified functions or steps, or combinations of special purpose hardware and computer instructions.

Disclosed methods and systems can be implemented to perform Test Power Analysis (TPA) on ICs to test and identify potentially hazardous vectors associated with high peak power/current. In an aspect, the analysis can be fast, accurate, vector-based and applicable to many, if not all, types of test pattern sets. The analysis can be technology aware and layout aware. The disclosed TPA can be applicable to both wire-bond and flip-chip designs. In an aspect, the disclosed TPA can be performed on hundreds or thousands of test cycles in one or more simulations run by integrating TPA engines in gate-level simulation through IEEE Verilog Procedural Interface (VPI).

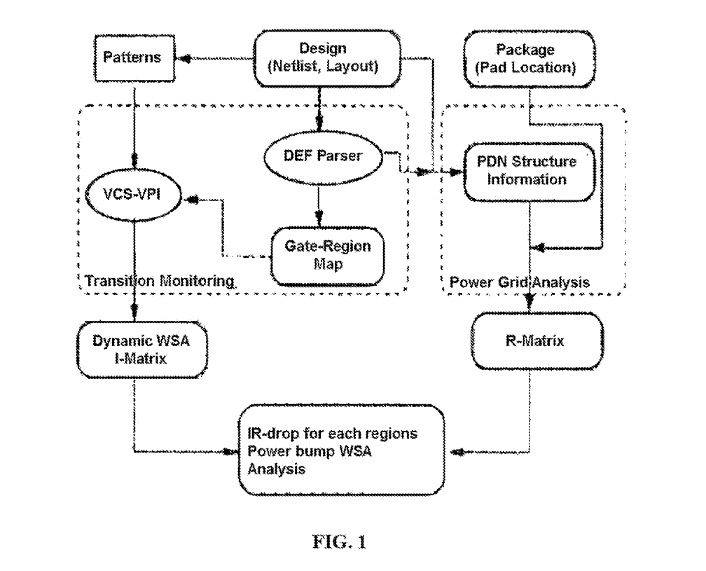

FIG. 1 shows a main infrastructure for performing a power analysis for test patterns. Design data can comprise a netlist and a layout (e.g., DEF or GDS). The netlist (e.g., a Verilog description) can be fed to an automated test pattern generation (ATPG) engine for generating any type of test pattern, such as stuck-at, delay fault, bridging fault, combinations thereof, and the like. The test patterns, along with netlist can be fed to a Verilog simulator, for example, Synopsys VCS. DEF files can be processed by a DEF parser which understands: (1) die area, (2) each cell location, (3) VDDNSS domains, (4) PDN structure, such as power rings and stripes on top metal. A DEF parser can understand PDN and partition the layout into a plurality of regions and can create an internal gate-region map. The internal map can be fed into the Verilog simulator for locating each signal switching site. A Verilog Procedural Interface (VPI) core can use a power model referred to as weighted switching activity (WSA), to translate each switching event to power/current equivalents and can create a dynamic WSA current matrix. In an aspect, power grid analysis can be performed using PDN structure information as well as pad location information from a specific package design. In an aspect, a resistance matrix for a specific design can be built. In another aspect, the dynamic current and resistance matrices can be combined to produce test power results such as dynamic voltage drop, hotspots, peak current on power pads, and the like. In another aspect, all analysis can be cycle-based, that is, all test cycles can be monitored in case there is any pattern with excessive power or current.

Power Model

Power dissipation in CMOS logic has two components: static and dynamic. Leakage power (static component) can remain a constant throughout an operation session and can be ignored in power modeling. In an aspect of the present disclosure, only dynamic power dissipation caused by charging and discharging of load capacitances is considered. The power consumption of each instance P can be obtained using Equation (1). Without considering voltage droop, supply voltage V can be assumed to be a constant, thus the two variants that could impact power would be load capacitance C_{L} and switching frequency f. In an aspect, switching frequency can be considered via transition monitoring. For low power designs with multi-VDD domains [1], supply voltage V can becomes a variable. In this case, DEF parser can be associate each instance with its power source level.

$$P = {C}_{L} * {V}^{2} * f \\ WSA = δ * {C}_{L} * {V}^{2} \\ {C}_{L} = {C}_{o} + {C}_{lumped\_wire} + {\sum }_{k = 1}^{n} {C}_{{input}_{k}} \qquad ( 1 )$$

In an aspect, WSA can be used to model current strength. It can be represented by energy consumption at each switching site and independent of test frequency. When zero delay model is considered, current spike can accumulate at the rising edge of each clock cycle, and the strength of the current spike can be proportional to energy consumption. In an aspect, WSA can be a good representative of peak current. o is a scaling factor used internally to normalize absolute energy values.

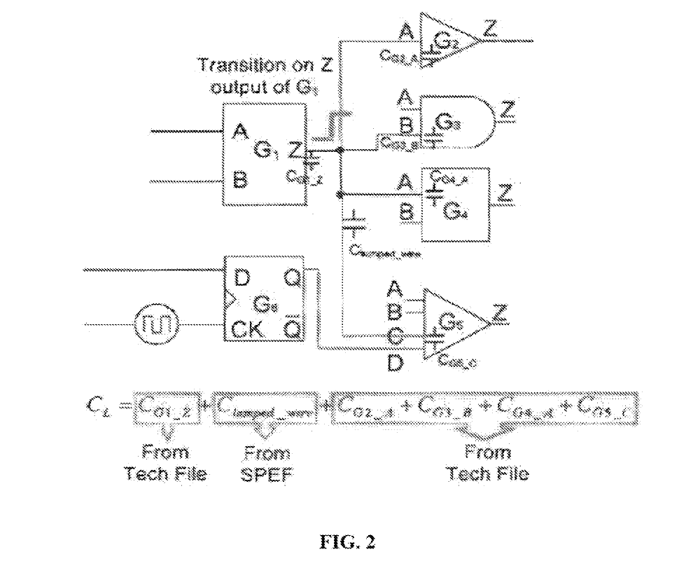

FIG. 2 illustrates a load capacitance calculation. Load capacitance C_{L} is the sum of output capacitance C₀, lumped interconnect capacitance C_{wire}, and input capacitances Cᵢₙₚᵤₜ of all fan-out gates, as shown in FIG. 2. In this example, there are six gates, from G₁ to G₆. Suppose there is a 0→1 transition taking place at the output pin Z of G₁, which has four fan-out gates, that is, A pin of G₂, B pin of G₃, A pin of G₄ and C pin of G₅. C_{L} can be obtained by considering the capacitance of three major items. More specifically, C₀ (e.g., C_{G1-z}) can be obtained from standard cell library files regarding G₁ cell type. C_{lumped}_{_{—}}_{wire} can be obtained from Standard Parasitic Exchange Format (SPEF) file from parasitic extraction. C_{c2A}, C_{c3B}, C_{c4A} and C_{c5c} can be obtained from standard cell library files as well. After C_{L} is calculated, the load capacitance value can be used to represent energy consumed by this transition. A real C_{L} value, in the unit of pico-farad, can be normalized, by factor δ and V² to a value that can be stored in an integer or float type of structure. The internal normalized value can be the WSA for this 0→1 transition at G₁.

Transition Monitoring

In an aspect, in order to observe the power behavior across an entire test session, including both shift and capture cycles, transition monitoring can be test cycle based. The disclosed method can monitor transitions along with a simulation process. More specifically, a VPI routine can be utilized to access internal simulation data while test patterns are applied and simulated. As an example, information collected during a simulation process can include: 1) rising edge of primary test clocks to determine the start and end time of each test cycle; 2) state of scan enable signal to determine the working mode, for example, shift or capture; 3) advent time of each transition to determine to which test cycle it belongs; and 4) fan-out gates of each transition, as well as the parasitic wire capacitance at the transition site. Collected information can be recorded cycle by cycle during simulation and analyzed to determine the number of transitions in a specific test cycle. Equation (1) can be applied to translate the transition information into WSA and power values for subsequent layout based analysis. In an aspect, the transition monitoring can be embedded in pattern simulation. All test cycles can be handled in batch processing. The equivalent power values can be recorded along with simulation internal structures.

Power Calculation

In an aspect, power consumption can comprise three parts: leakage, internal and switching power, among which the leakage can be static while the internal and switching power can be dynamic. Leakage can be calculated by summing up leakage power of all instances, which can be looked up from cell or block Liberty files. Dynamic power can be based on transition monitoring. Whenever a transition is detected, information such as the switching cell type, its loading capacitance as well as transition time (e.g., slew rate) can be determined by VPI routine. The information combined with voltage level, clock period, can be used to calculate switching and internal power. The disclosed methods and systems can sum up three power parts for each test cycle, and thus can monitor total average power consumption cycle by cycle. In an aspect, average power calculation can rely on standard cell library and transition monitoring, and can be independent of physical structure, such as place and route, power delivery or package.

Layout Partition and Regional Power

In an aspect, in order to locate transitions in the circuit, topology (e.g., layout) information can be used to identify location of each gate. As an example, a DEF file can be used to extract gate coordinates, as well as the power supply network. A two-dimensional array (matrix) can be overlaid on top of the layout that divides it into smaller partitions.

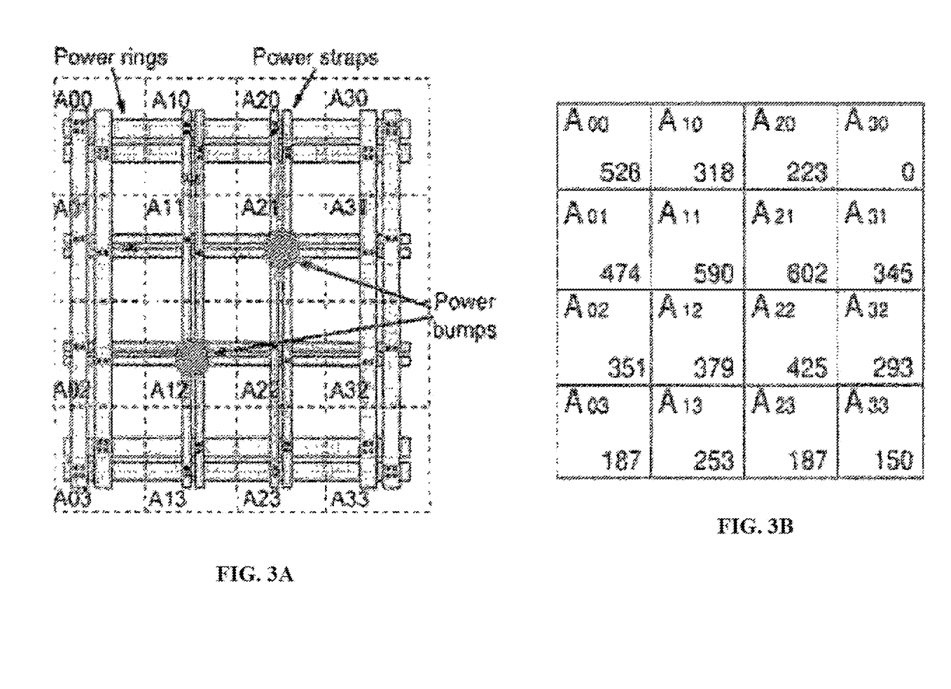

FIG. 3A illustrates an example of the power straps being used to partition a layout into a plurality of regions and FIG. 3B illustrates an example of a WSA_{A} matrix. In an aspect, FIG. 3A illustrates how a physical design of an IC can be divided into smaller regions based on the power supply network. In this example, there are two straps vertically across the chip in Metal 6 (M6), two horizontally across the chip in Metal 5 (MS), and power/ground rings around the periphery of the design. Using the straps as midpoints for each region in the matrix, the chip can be divided into four columns and four rows for a total of sixteen (16) regions. Two power bumps can be located above the regions of A₁₂ and A₂₁ (A stands for each area or region), connecting to two separate power straps respectively. In the case where there are only straps either vertically or horizontally, the direction with the straps can be divided in the same manner, while the strapless direction can be divided evenly by the same number of regions in the direction of straps.

In one aspect, the partition matrix can be created once for each design. When a switching is detected, the location of the switching instance can be looked up and mapped to a region in the matrix, for example, Aᵢⱼ, then WSA calculated using Equation (1) for that instance can be added to the region Aᵢⱼ. When simulation ends, each region can be filled with a sum of WSA of instances. WSA_{A} can be defined as WSA related to a specific region, as shown in Equation (2). As an example, when applying a delay test pattern, all regions having WSA_{A} can be initialized to 0 at the beginning of launch-to-capture cycle. When the same cycle ends, the matrix with each region Aᵢⱼ can have a one-to-one mapped WSA_{A}, as shown in FIG. 3B.

$${WSA}_{{A}_{i , j}} = {\sum }_{k = 1}^{n} {WSA}_{{instance}_{k}} , instance k is in region ( i , j ) . \qquad ( 2 )$$

Each region in the matrix can have a WSA_{A} value that represents the amount of current needed from a power supply, which can be combined with a resistance network to determine how much current that region can draw from each power bump. In an aspect, a region with a 0 value (WSA_{A}=0) in the matrix implies no switching in the region or even no instance placement. This can potentially happen in peripheral regions.

In an aspect, circuit test power calculation can be simplified by assigning a group of instances to a virtual region and analyzing the regional power, which equals the sum of each individual component's power falling into that region. As a result, a power grid model can be simplified by analyzing a regional power grid model instead of for each instance node. When partitioning the layout of a circuit, the components in each region can have similar power grid characteristic, which can impose a limitation on the maximum region size. In an aspect, too large a region can lose details of current flow along power grid over the region, and can make a bump's current value indistinguishable around the region, whereas too small a region can have numerous tiny partitions, the power grid characteristic of which can still require extensive computation time for solving node voltage or current. In an extreme scenario, each standard cell or memory cell can take up one region. In an aspect, global Power Distribution Network (PDN) can be the start point of layout partitioning. For example, location of power straps and rails on highest metal layer (M6) can be used for dividing layout into N×N regions [2]. For industry designs, as one example in FIG. 3A, which has II metal layers, power and ground bumps can be connected to the widest metal layer (M11), then M10, M8 by vias, till the narrowest layer M1 that provide supply voltage for standard cells on a die. The top view in FIG. 3B shows there are 15 bumps over the core area: two rows of VDD bumps and one row of VSS bumps. With similar consideration with [2], the grains of topmost metal layer M11 can be utilized for layout partitioning. In this example, the VDD and VSS bump coordinates can be aligned for establishing borders of partitions.

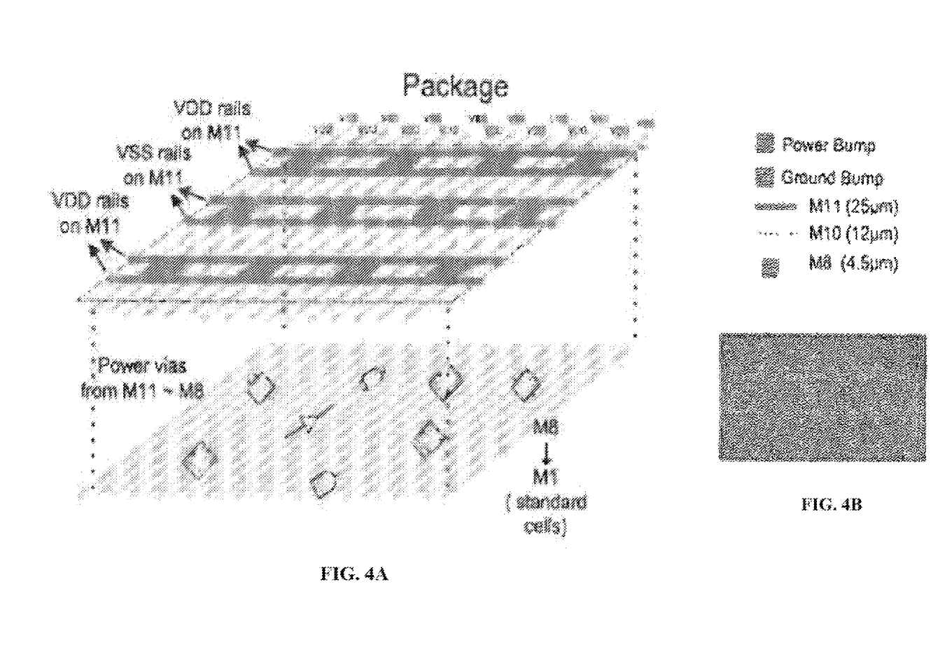

FIG. 4A illustrates a side view of standard cells, power bump cells and metal 8 to 11 of a power network structure for an industry circuit design. FIG. 4B illustrates top view of standard cells, power bump cells and metal 8 to 11 of a power network structure for an industry circuit design. In an aspect, each region can be a regular shape with similar size, while bumps can be evenly distributed among the regions. Take the case in FIG. 3B as an example. As bumps can be aligned in both rows and columns, partition border lines can be created between two adjacent bumps, as shown in FIG. 4A. It is a 7×3 partition scheme, with 15 bumps falling into the middle regions. Another partitioning scheme on the same design is introduced in FIG. 4B to decrease the size of each partition. Extra vertical lines (drawn in dotted line) can be inserted between original adjacent vertical lines in FIG. 4A to make the number of vertical partitions as 13. In an aspect, the horizontal partitions need to be increased to maintain a square shape for each region. Consider the core aspect ratio of 1:1.89, the number of horizontal partitions can be re-determined to be 8. 13×8 partition scheme in FIG. 4B can be used for subsequent analysis.

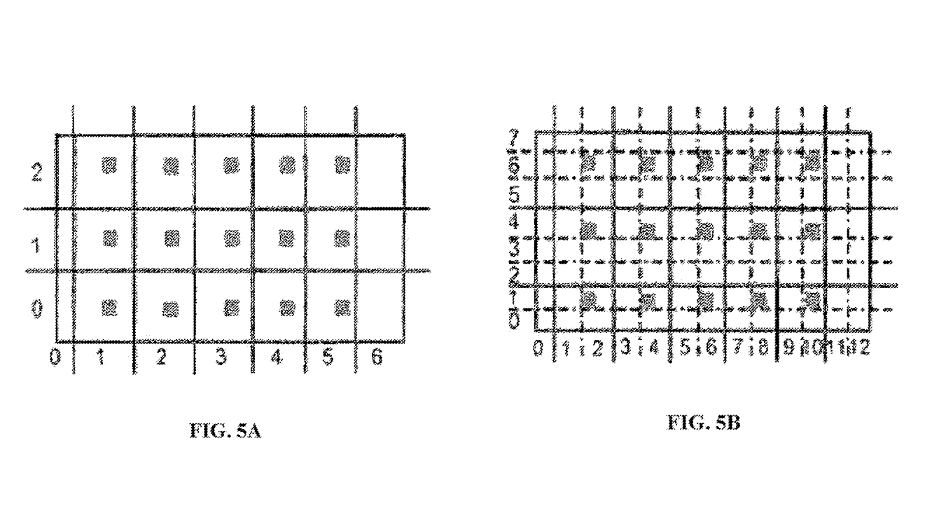

FIG. 5A illustrates a 7×3 partitioning based on power bump location and FIG. 5B illustrates a 13×8 partitioning based on power bump location. In an aspect, regional WSA_{A} representing power level in a region can be used to study regional power consumption. Mathematically, WSA_{A} equals the sum of WSA of all switching instances in the region, as shown in Equation (3). WSA_{A} can vary cycle by cycle. Especially during scan loading, random bits can be shifted in scan chains, triggering different parts of the circuit to switch. An example of WSA_{A} is illustrated in FIG. 5. It is based on the partitioning scheme shown in FIG. 4B for an industry circuit. The related cycle is one of a plurality of shift cycles. The numbers show different levels of power consumption in the local area. A₀ indicate no switching within that area.

$${WSA}_{A} = {\sum }_{i = 1}^{n} {WSA}_{{instance}_{i}} , for one test cycle \qquad ( 3 )$$

Power Grid Analysis

In high performance digital ICs, power and ground distribution networks are typically designed hierarchically. A grid structured network can be widely used for global PDN design, while the structure for local PDN, also called block level PDN can be different from block to block. Typically, the lower the metal layer, the smaller the width and pitch of lines, as shown in FIG. 4A. Suppose there are 11 metal layers. Power bumps can be connected to the top horizontal metal layer M11. The lowest level power/ground (P/G) lines on M1 can run horizontally as power rails. Standard cells can be arranged in rows and connected to M1 P/G wires with two adjacent rows sharing the same power line. There can be numerous resistive paths from a power bump to a region, for example, P_{ath1 . . . r} resistive value for these paths can be Rₚₐₜₕ₁//Rₚₐₜₕ₂//Rₚₐₜₕᵣ. In an aspect, the least resistance path (LRP) can be used to represent the resistive path value, shown in Equation (4). If there are M power bumps in the package, the PDN for that region can be its parallel resistance paths to all power bumps, given in Equation (5).

$$\begin{matrix}{R}_{{region}_{i , j} -> {bump}_{m}} = {R}_{LRP} & ( 4 ) \\ {R}_{{region}_{i , j}} = \frac{1}{{\sum }_{m = 1}^{M} ( 1 \text{/} {R}_{{region}_{i , j} -> {bump}_{m}} )} & ( 5 )\end{matrix}$$

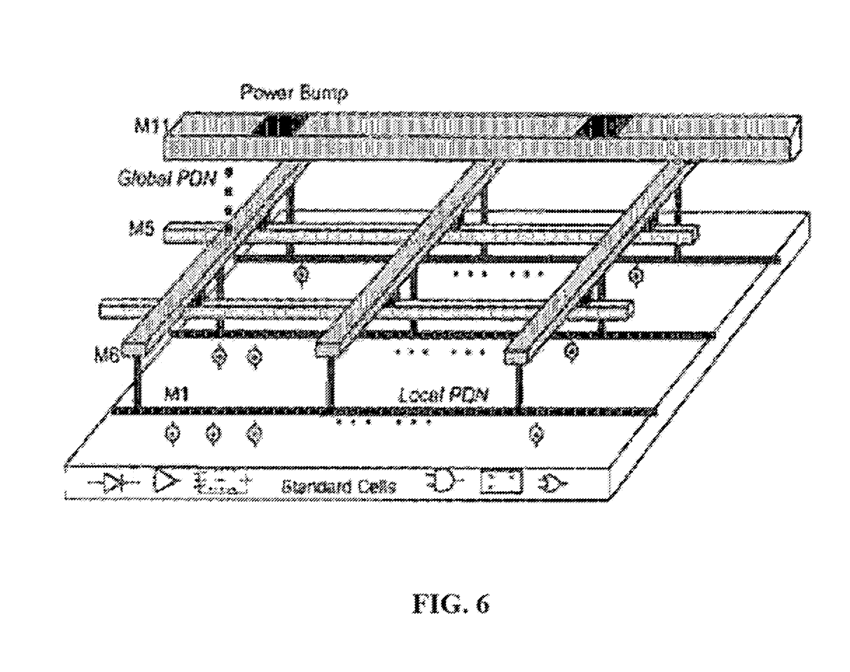

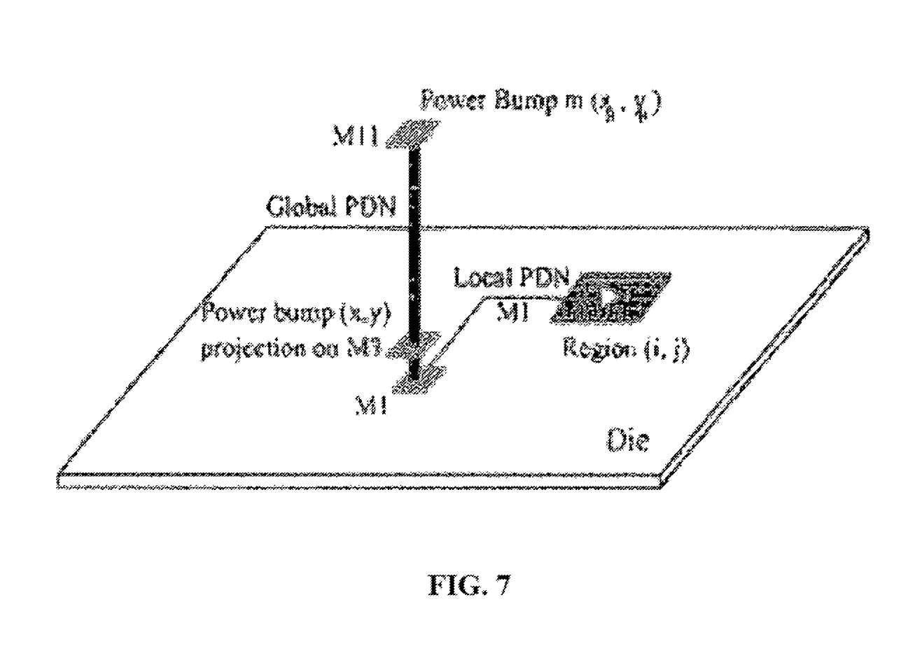

FIG. 6 shows a grid structured PDN for an industry design. Power bumps can be connected to the top horizontal metal layer M11, M6, M5 and lowest M1 layers are shown to illustrate the internal hierarchical structure, while hiding other metal layers in between for simplicity. The lowest level power/ground (P/G) lines on M1 run horizontally as power rails. Standard cells can be arranged in rows and connected to M1 P/G wires with two adjacent rows sharing the same power line. M11→M3 can be regarded as global PDN, while M1 and M2 as local PDN. FIG. 7 illustrates a resistive path from one power bump to a region. Two types of PDNs are abstracted and illustrated in FIG. 7. The least resistive path from a power bump to a region can comprise a global PDN that is vertical power via stack from power bump to its projection on M3, and a local PDN which is the rail path from M3 to M1 then to region center. In a typical industry PDN design, a local PDN can take up 80% of the resistance in a resistive path due to the small width of power line, while the global PDN can account for the remaining 20%. Equation (6) can be used to model the resistive path value from supply to a region, coefficient 0.8 and 0.2 can be weights assigned to two PDN components. More specifically, resistance of local PDN can be the square distance between bump and region coordinates. The coordinates {x_{B}, y_{B}} of a bump can be the layout partition index of its projection on a die. The coordinates {i, j} of region can be horizontal and vertical partition indices. In an aspect, global PDN resistance can be treated as constant. If there are M power bumps in the package, PDN for that region can be its parallel resistance paths to all power bumps, given in Equation (7). G is the conductance value.

$$\begin{matrix}{R}_{{region}_{i , j} -> {bump}_{m}} = 0.8 \times {R}_{{M}_{local}} + 0.2 \times {R}_{{M}_{global}} \\ {R}_{{M}_{local}} = \vert {x}_{B} - i \vert + \vert {y}_{B} - j \vert \\ {R}_{{M}_{global}} is a fixed value . & ( 6 ) \\ {G}_{{region}_{i , j}} = \frac{1}{{\sum }_{m = 0}^{M} {R}_{{region}_{i , j} -> {bump}_{m}}} & ( 7 )\end{matrix}$$

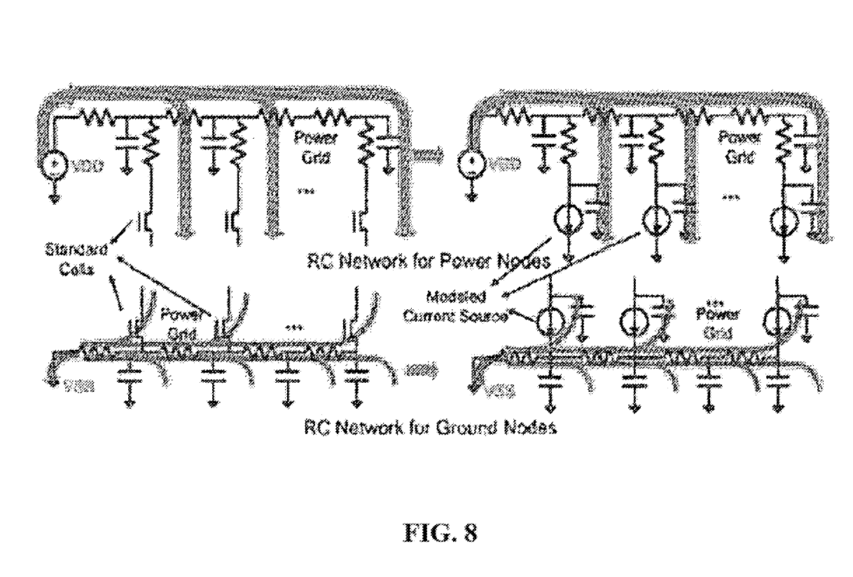

The ground network can be considered in resistive network as well. FIG. 8 shows RC modeling for power and ground nodes. Left column is schematic view for VDD and VSS current flows. Standard cells can be modeled as current sources, and their RC models are shown in the right column. Current can flow from power source (VDD bump) to standard cells, and can flow back to ground sources (VSS bump). The voltage swing on instances' power pins can take into consideration both voltage drop on power network and voltage rise on ground network. Similar PDN analysis can be conducted toward ground network. If there are M power bumps and N ground bumps, an updated PDN resistance for a layout region can be given in Equation (8).

$${G}_{{region}_{i , j}} = \frac{1}{{\sum }_{m = 0}^{M} {R}_{{region}_{i , j} -> {bump}_{m}} + {\sum }_{n = 0}^{N} {R}_{{region}_{i , j} -> {bump}_{m}}} \qquad ( 8 )$$

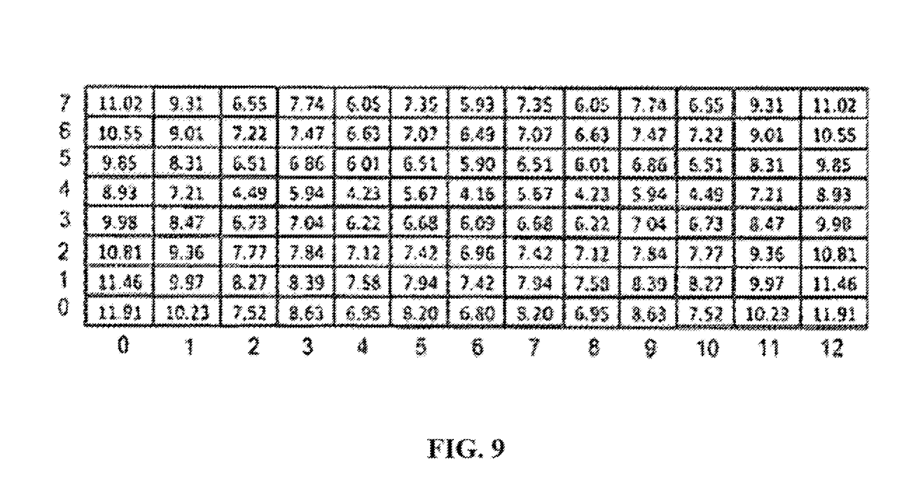

An example of resistance network is illustrated in FIG. 9 for the partition scheme in FIG. 5B. All resistance values in the regions are normalized. The maximum R appears on the four corners, as none of regions are geographically close to the majority of power and ground bumps. The least R appears in region (6,4) with value 4.16. It has shortest resistive paths to bumps. Power can be supplied most efficiently in the region (6,4). There is least chance for the region to experience high peak current or excessive IR-drop.

Power Bump WSA Analysis

In an aspect, suppose the layout is partitioned into X×Y regions. The package has M power bumps, N ground bumps. WSA_{A} is obtained for all regions during one test cycle. Bump WSA for the cycle can be represented, WSA_{Bm}, as the WSA for power or ground bump m, reflecting the amount of current drawn from or sink to the bump. Equation (9) can be understood as WSA on a power bump m draws a portion of WSA from each region. The ratio for each region can be determined by the region's resistive path to bump m versus to all power bumps.

$${WSA}_{{B}_{m}} = {\sum }_{i = 0}^{X} {\sum }_{j = 0}^{Y} {WSA}_{{region}_{i , j}} \times \frac{{G}_{{region}_{i , j} -> {bump}_{m}}}{{\sum }_{k = 1}^{M + N} {G}_{{region}_{i , j} -> {bump}_{k}}} \qquad ( 9 )$$

Power Validation Flow

In an aspect, the disclosed methods and systems can be used to monitor peak power and current across an entire test session. A plurality of subsequent measures can be taken for the test power reduction or safety purposes, such as locating hotspots during test, test pattern short-listing based on peak power or current, power probes assignment for balancing current delivery during wafer test, and the like. The disclosed methods can be specifically adapted to perform dynamic test power analysis in a fast manner without losing power results accuracy. The disclosed methods and systems can be compared with a commercial back-end power-integrity sign-off tool. Test results can comprise one or more of: (1) switching activity report; (2) absolute power report; (3) WSA_{A}*R matrix plots, which can be compared with Dynamic Voltage Drop (DvD) plots in a commercial tool; (4) power bump WSA, which can be correlated with absolute power bump current reported by commercial tool.

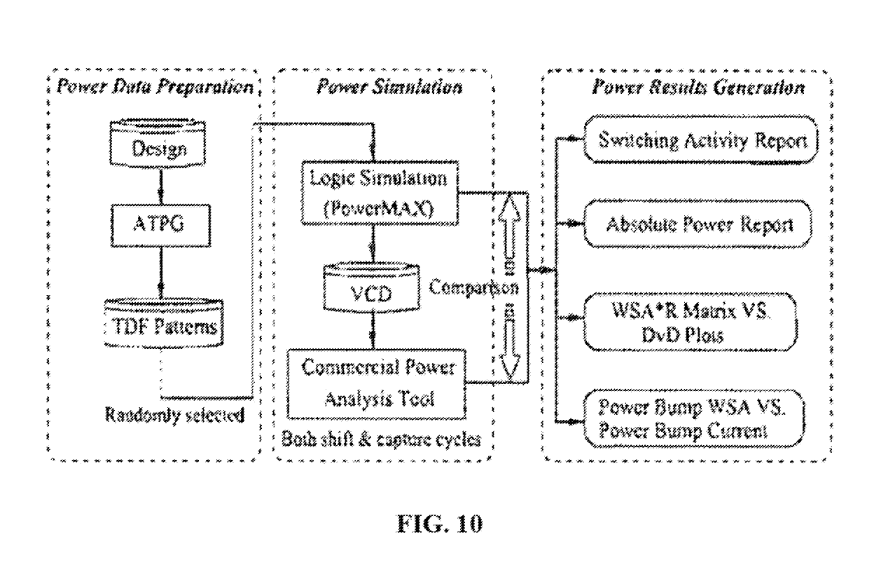

The validation steps are illustrated in FIG. 10. The first column of the validation flow can be power data preparation stage, where design netlist can be fed to ATPG tool for TDF pattern generation. A plurality of randomly selected patterns can be selected from an original pattern set as power simulation input data. The second column can be power simulation stage. Power simulation stage can use both the disclosed methods and a commercial tool. In an aspect, the commercial tool can use VCD files dumped from logic simulation as an input. In this stage, a plurality of shift and capture cycles can be selected for power simulation and results collection. The third column can be power results generation covering all above mentioned types of power results. Comparison can be made between the disclosed methods and the commercial tool. WSA related results can be obtained by the disclosed methods, whereas DvD plots and power bump current are results from a commercial tool.

In an aspect, compressed TDF patterns can be generated. A plurality of patterns can be randomly selected for serial simulation. Value change dump (VCD) files can be stored for all levels of design toward entire simulation session. Test power analysis VPI routine can be embedded in simulation. In an aspect, regional WSA and resistance network can be obtained. All power bumps' WSA can be calculated cycle by cycle. Based on the VCD files, a commercial EDA tool can perform dynamic power and rail analysis. In an aspect, IR-drop plots can be obtained for several test cycles, which can be compared with WSA*R plots to locate hotspots. Real power bump current can be obtained cycle by cycle, which can be correlated with power bump WSA values.

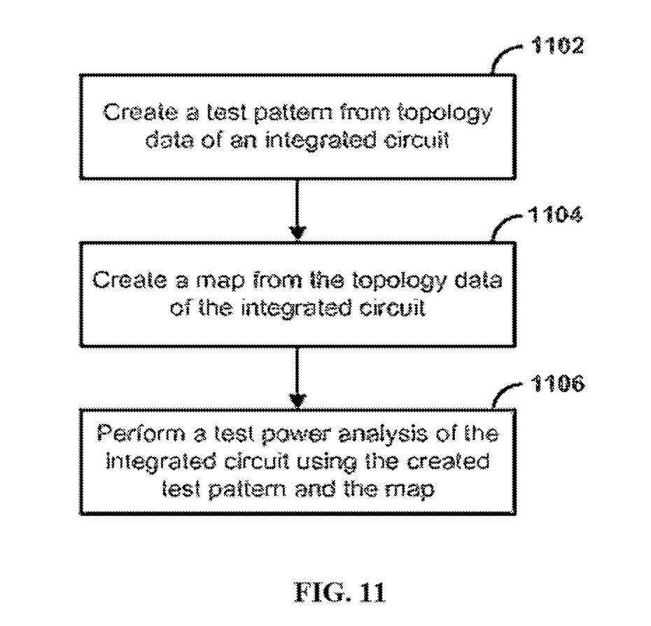

In an aspect, illustrated in FIG. 11, provided are methods for test power analysis. At step 1102, a test pattern from topology data of an integrated circuit can be created. As an example, the test pattern can comprise one or more of stuck-at pattern, bridging-fault pattern, transition-delay pattern, path-delay pattern. In an aspect, the topology data can be fed to an automated test pattern generation (ATPG) engine for generating any type of test pattern, such as stuck-at pattern, delay-fault pattern, bridging-fault pattern, and the like. In an aspect, the topology data can comprise a Verilog description. The topology data can comprise layout data. As an example, the topology data can comprise die area, cell locations, voltage drain drain (VDD) domains, voltage source source (VSS) domains, power delivery network (PDN) structure. The topology data can enable localized power consumption analysis and power delivery on power mesh networks.

At step 1104, a map from the topology data of the integrated circuit can be created. In an aspect, the map can be a gate-region map. The map can be generated using a parser, such as a DEF parser. For example, in order to locate transitions in the integrated circuit, topology information can be used to identify a location of each gate. As an example, a DEF file can be used to extract gate coordinates, as well as the power supply network. A two-dimensional array (matrix) can be overlaid on top of the topology data that divides it into smaller partitions.

At step 1106, a test power analysis of the integrated circuit can be performed using the created test pattern and the map. In an aspect, performing a test power analysis can comprise generating a dynamic weighted switching activity (WSA) current matrix from the created test pattern and the created map. In an aspect, the dynamic weighted switching activity (WSA) current matrix can be generated using a simulator. For example, a Verilog Procedural Interface (VPI) core can use a power model called weighted switching activity (WSA), to translate each switching event to power/current equivalents and creates a dynamic WSA current matrix. In an aspect, the dynamic weighted switching activity (WSA) current matrix can comprise a plurality of regional WSA current matrices. Each regional WSA matrix can have a WSA_{A} value that represents the amount of current needed from power supply, which can be combined with a resistance network to determine how much current that region can draw from each power bump. In an aspect, a region with a 0 value (WSA_{A}=0) in the matrix implies no switching in the region or even no instance placement. This can potentially happen in peripheral regions.

In another aspect, performing a test power analysis can further comprise obtaining package data of the integrated circuit and generating a resistance matrix from the topology data and the package data. As an example, the package data comprises wire bond package data and flip chip package data. In an aspect, power grid analysis can be performed using PDN structure information as well as pad location information in the obtained package data and a resistance matrix for the specific package data can be built. The dynamic current and resistance matrices can be combined to produce test power results such as dynamic voltage drop, hotspots, peak current on power pads, and the like. All analysis can be cycle-based, that is, all test cycles can be monitored in case there is any pattern with excessive power or current.

In an aspect, a test power analysis can comprise one or more of: switching activity analysis, average power analysis, regional power analysis, peak current data analysis, current distribution analysis. In an aspect, performing the average power analysis can comprise using power data from a standard cell library.

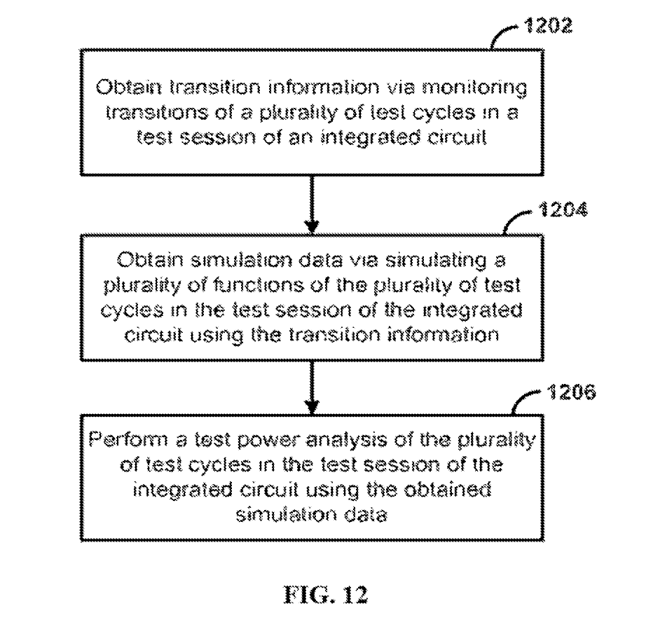

In an aspect, illustrated in FIG. 12, provided are methods for test power analysis. At step 1202, transition information can be obtained via monitoring transitions of a plurality of test cycles in a test session of an integrated circuit. As an example, the plurality of test cycles can comprise one or more shift cycles, one or more capture cycles, or combination thereof. As an example, the transition information can comprise switching cell type, loading capacitance, transition time.

At step 1204, simulation data can be obtained via simulating a plurality of functions of the plurality of test cycles in the test session of the integrated circuit using the transition information. In an aspect, the simulation data can be obtained via a Verilog procedural interface (VPI). The VPI can retrieve simulation data from a simulation engine, combined with extra read-in topology data, and performs a serial analysis to obtain power data and current data for each simulation cycle. As an example, the simulation data comprises one or more of start time of a test cycle, end time of a test cycle, type of a test cycle, relation of a specific transition and a specific test cycle, fan-out gates, and parasitic wire capacitance at a transition site. As an example, rising edge of primary test clocks can be used to determine start and end time of each test cycle. As another example, state of scan can be used to determine type of test cycles such as shift cycles or capture cycles. As another example, advent time of a transition can be used to determine to which test cycle the transition belongs. As another example, fan-out gates of each transition and parasitic wire capacitance at the transition site can be determined. All simulation data can be recorded cycle by cycle during simulation and analyzed to determine the number of transitions in a specific test cycle.

At step 1206, a test power analysis of the plurality of test cycles in the test session of the integrated circuit can be performed using the obtained simulation data. In an aspect, performing a test power analysis can comprise translating simulation data to weighted switching activity (WSA) and power value. In an aspect, the power value can comprise power leakage value, internal power value and switching power value. In an aspect, monitoring transitions of a plurality of test cycles in a test session and simulating a plurality of functions of the plurality of test cycles in the test session can occur simultaneously. In another aspect, the test power analysis can be performed along with the simulation at step 1204. Thus, when simulation is finished, power values and/or current values can be available.

The present methods and systems can be operational with numerous other general purpose or special purpose computing system environments or configurations. Examples of well known computing systems, environments, and/or configurations that can be suitable for use with the systems and methods comprise, but are not limited to, personal computers, server computers, laptop devices, and multiprocessor systems. Additional examples comprise set top boxes, programmable consumer electronics, network PCs, minicomputers, mainframe computers, distributed computing environments that comprise any of the above systems or devices, and the like.

The processing of the disclosed methods and systems can be performed by software components. The disclosed systems and methods can be described in the general context of computer-executable instructions, such as program modules, being executed by one or more computers or other devices. Generally, program modules comprise computer code, routines, programs, objects, components, data structures, etc. that perform particular tasks or implement particular abstract data types. The disclosed methods can also be practiced in grid-based and distributed computing environments where tasks are performed by remote processing devices that are linked through a communications network. In a distributed computing environment, program modules can be located in both local and remote computer storage media including memory storage devices.

The methods and systems can employ Artificial Intelligence techniques such as machine learning and iterative learning. Examples of such techniques include, but are not limited to, expert systems, case based reasoning, Bayesian networks, behavior based AI, neural networks, fuzzy systems, evolutionary computation (e.g. genetic algorithms), swarm intelligence (e.g. ant algorithms), and hybrid intelligent systems (e.g. Expert inference rules generated through a neural network or production rules from statistical learning).

### Examples

The following examples are put forth so as to provide those of ordinary skill in the art with a complete disclosure and description of how the compounds, compositions, articles, devices and/or methods claimed herein are made and evaluated, and are intended to be purely exemplary and are not intended to limit the scope of the methods and systems. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

Power Results

Power validation flow, including the disclosed methods and a commercial tool, was performed on a plurality of hierarchical industrial hard macros, A and B with 168, 136 and 1,199,930 gates respectively. The plurality of hard macros comprising tens of VDD bumps and VSS bumps evenly distributed over core area. TDF patterns were generated using Mentor Graphics' Test Kompress. 10 randomly patterns were selected from Macro A for result collecting, including both shift and capture cycles. Pattern simulation, integrated with the disclosed methods was running using Synopsys VCS. 64 bit Linux server was used with 2.4 GHz CPU and 8G RAM memory for the power validation. Table I shows the average CPU runtime of one test cycle for the disclosed method and the commercial power tool. As an example, for a smaller macro A, the disclosed method can be 110 faster than commercial tool in terms of dynamic test vector power analysis. For a larger macro B, The disclosed methods can be 43 times faster.

TABLE I
CPU RUNTIME OF POWERMAX AND COMMERCIAL TOOL

| | Commercial Tool | PowerMAX | PowerMAX |
|---|---|---|---|
| Hard Macro | (time/cycle) | (time/cycle) | Speedup |
| Macro 1 | 770 sec | 7 sec | 110x |
| Macro 2 | 2600 sec | 60 sec | 43x |

Switching Activity Analysis

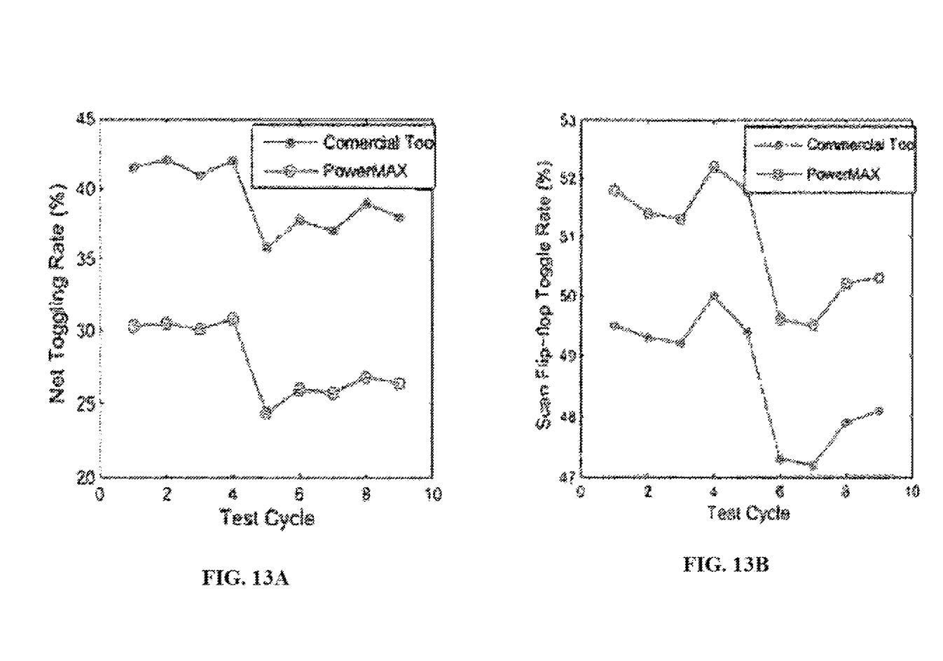

The disclosed methods and systems can provide switching activity calculation for both signal nets and scan flip-flops. FIG. 13A and FIG. 13B shows switching activity comparison from the disclosed method and commercial tool for randomly chosen nine consecutive test cycles. FIG. 13A illustrates net toggling rates comparison between the disclosed method and a commercial tool. FIG. 13B illustrates scan flip-flop toggling rates comparison between the disclosed method and a commercial tool. The overall curve trends correlates well, except for a −10% offset in net toggle and +2% offset in scan flip-flop. The negative offset in the net toggle can be due to different internal statistical count of net signals, and the positive offset in scan flip-flop can result from that the disclosed method considers switching of Q of flip-flop as a separate toggle.

Average Power Report

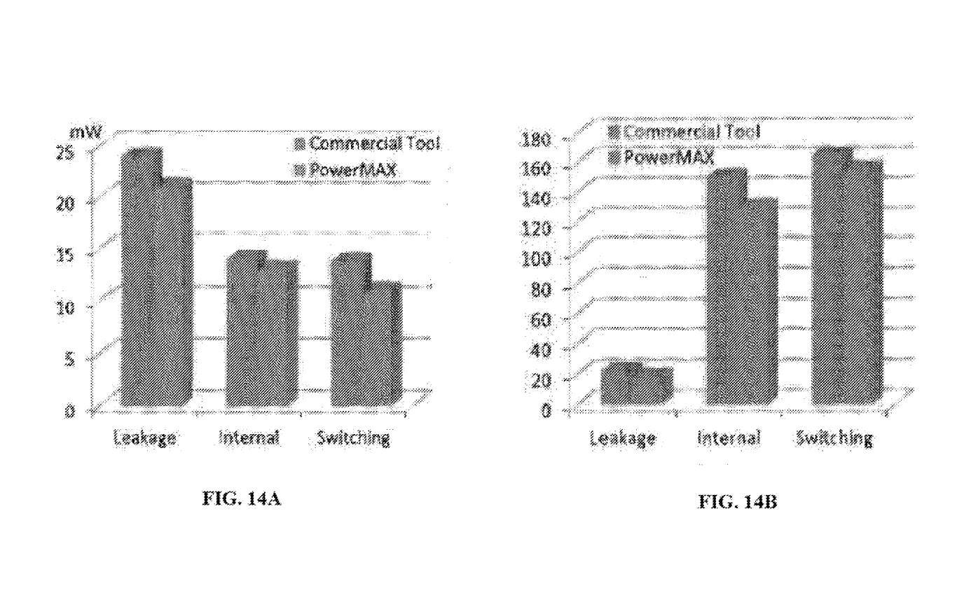

FIG. 14A illustrates average power comparison between the disclosed method and a commercial tool for P.S_S.1. FIG. 14B illustrates average power comparison between the disclosed method and a commercial tool for P.5_C.1. One typical shift cycle and one capture cycle were chosen for absolute power comparison between the disclosed method and commercial tool regarding Hard Macro A. Shift cycles can be referred as P.5_S.1, and capture cycle can be referred as P.S_C.1, wherein P indicates pattern index, S for shift cycle and C for capture cycle. The three power elements: leakage, internal and switching power are compared, as shown in FIG. 14. As capture frequency is much higher than shift frequency, the average capture power is much larger, as compared between FIGS. 14A and 14B. Average power differences between the disclosed methods and commercial tool are within 10%.

Hotspot Analysis

DvD analysis is performed to validate the power grid robustness and detect local hotspot. Extensive switching or a non-robust power grid usually experiences large voltage drop on an instance. If a group of clustered instances experience large voltage drop together, the respective region is a hotspot. The disclosed method can combine regional WSA matrix, as exemplified in FIG. 3B and regional resistance matrix to construct WSA*R report for each cycle, which gives an indication of whether voltage source is sufficiently provided for a local region. In an aspect, color maps can be used to plot WSA*R, with dark red to emulate largest voltage drop and dark blue as smallest voltage drop. Six test cycles are listed in Table II. The cycles in Table II are arranged in descending order by peak bump WSA (3rd column), which is the largest bump WSA among all power bumps within a test cycle. The second row (P.4_S.290) has the largest peak bump WSA among the six test cycles, as well as largest WSA_{A}×R (5th column) Similarly, the cycle's absolute peak current (4th column) and worst IR drop (6th column) reported by commercial tool are largest among them. P.9_C.1 experiences least voltage drop in these cycles, reflected in both the disclosed method and the commercial tool. There is a bump peak current (4th column) saturation phenomenon observed for the first four cycles when current value is over 1 A. The saturation can be due to on die decoupling capacitances which the commercial tool takes into consideration during power analysis.

TABLE II
SIX TEST CYCLES WITH DIFFERENT
POWER LEVEL AND HARD MARCO A.

| Pattern | | Peak | Peak Bump | | Worst |
|---|---|---|---|---|---|
| No. | Cycle | Bump | Current | Worst | IR-drop |
| (LOC) | No. | WSA | (A) | WSA_{A} * R | (mV) |
| P.4 | S.290 | 14609 | 1.06 | 10904 | 206.2 |
| P.4 | S.265 | 11282 | 1.05 | 9102 | 200.8 |
| P.9 | S.290 | 9831 | 1.00 | 8721 | 179.0 |
| P.2 | S.273 | 7726 | 1.00 | 6513 | 161.2 |
| P.2 | C.1 | 5091 | 0.46 | 5919 | 150.1 |
| P.9 | C.1 | 3368 | 0.29 | 3267 | 121.5 |

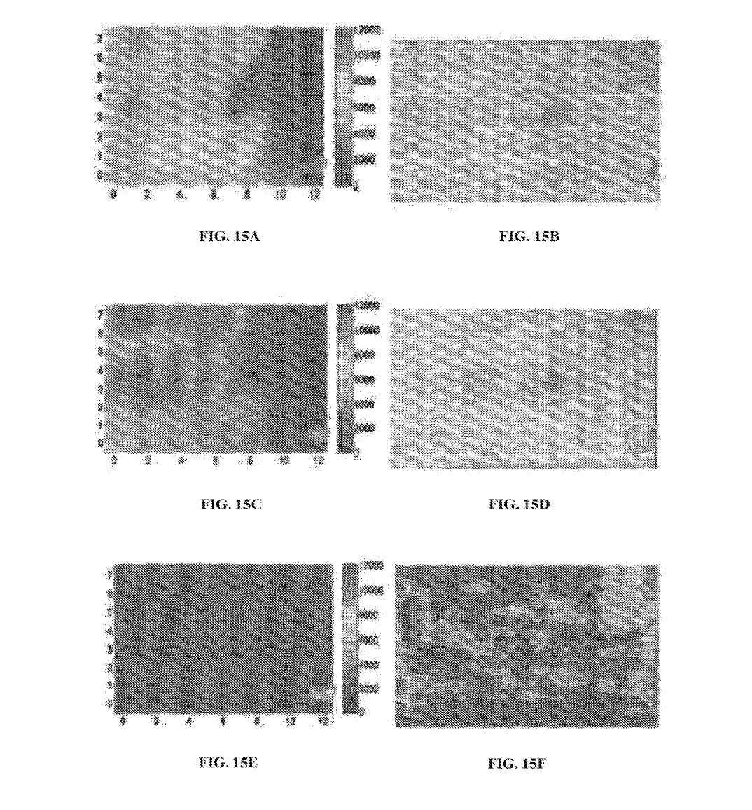

The voltage drop plots for three cycles: P.4_S.290, P.2_S.273 and P.9_C.1, are shown in FIG. 15. FIG. 15A illustrates WSA*R plots for P.4_S.290. FIG. 15B illustrates IR-drop plot for P.4_S.290. FIG. 15C illustrates WSA*R plots for P.2_S.273. FIG. 15D illustrates IR-drop plot for P.2_S.273. FIG. 15E illustrates WSA*R plots for P.9_C.1. FIG. 15F illustrates IR-drop plot for P.9_C.1. Left column is WSA*R plots, which are the products of regional WSA matrix and R matrix. A smoothened option is used to obscure the borders between two adjacent regions. A local hot spot around region (12,0) was observed as circled in all the six plots. Overall, P.4_S.290 has most red/yellow regions in both FIGS. 15A and 15B, indicating most switching activity in this cycle. P.9_C. 1 is the quietest pattern among the three, as demonstrated in FIGS. 15E and 15F. In an aspect, WSA*R can be plotted cycle by cycle in batch processing. There may be different local hotspots in different test patterns or cycles.

IR-Drop Analysis

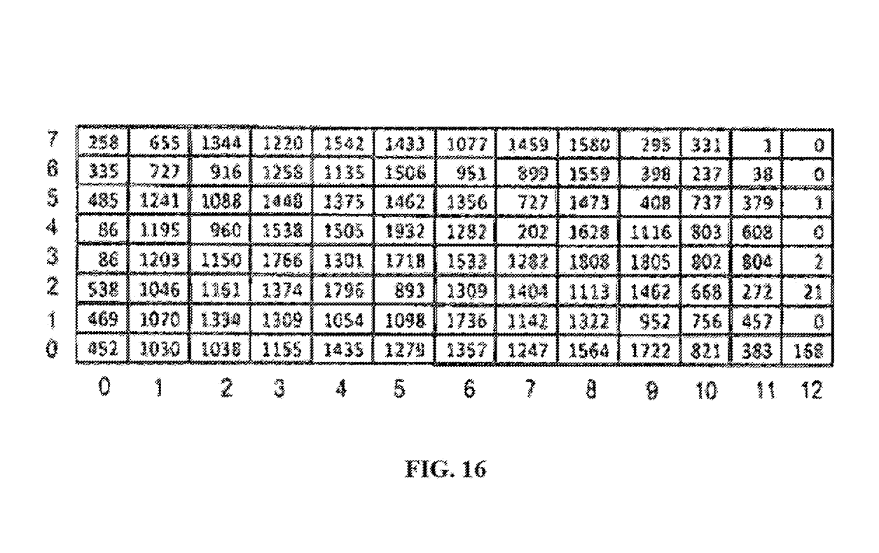

IR-drop analysis is performed to validate the robustness of power grid and detect local hotspot. Extensive switching in the design or ill designed power grid can experience large voltage drop on the components. FIG. 16 illustrates regional WSA example for one shift cycle of a LOC pattern in an IC design. The regional WSA matrix, as exemplified in FIG. 16 reflects the switching activity in each area, while resistance network as shown in FIG. 9 represents the power grid's robustness for each area. The combination of two, WSA*R gives an indication of whether voltage source is sufficiently provided for a local region. Similar to IR-drop plots, we use color-coded maps to plot W SA*R, with dark red as largest voltage drop and dark blue as smallest voltage drop.

WSA/Current Correlation Analysis

The correlation between bump WSA and current is analyzed. Data points for shift and capture cycles are collected separately. In order to analyze the battery current or current strength on each power pad/bump, the disclosed method can internally calculates WSAs. 43,500 total data points were selected for all shift cycles in the 10 randomly selected patterns. On one specific VDD or VSS bump, the data points are 2,900. Commercial power sign-off tool also performed power pad current analysis on selected test cycles. The correlation between WSA8 and absolute current on each power bump was observed to around 97%. Because of the good correlation, WSA8 can be used to estimate absolute current value by establishing a linear model between these two variables, as shown in Equation (10), where A is the scaling factor and B is the offset. 10% of all data points are chosen for establishing linear model between WSA8 and current, and estimated the rest 90% of data points. Most of the power pad absolute current estimation error is with 5%.

I=A*wsa+B (10)

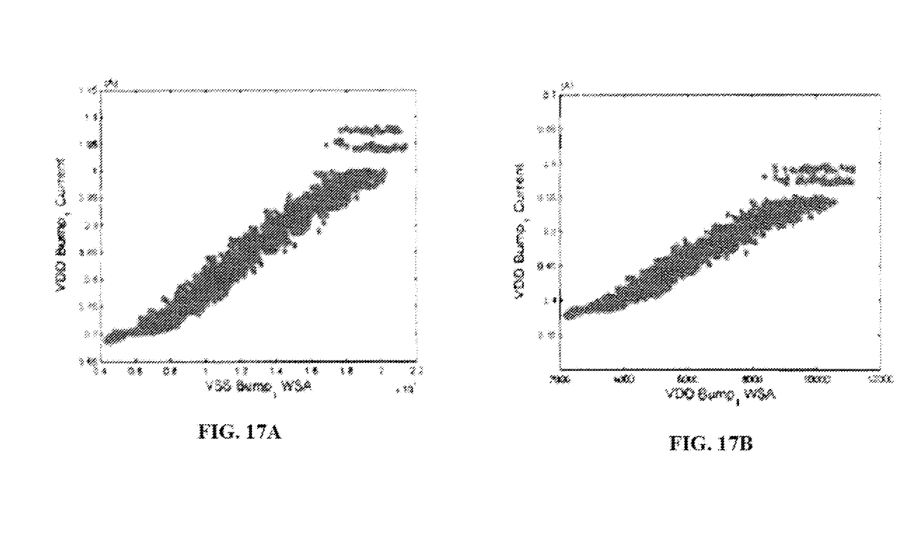

As there are much more shift cycles than capture cycles in typical TDF patterns, correlation between shift WSA and current are studied. There are 43,500 total data points for all shift cycles in the 10 randomly selected patterns. On one specific VDD or VSS bump, the data points are 2,900. Correlation result of current behavior for each power bump is given in Table III. A 0.98 correlation coefficient for almost all power bumps are observed. FIG. 17A illustrates relationship between WSA and current for VSS bump (2,4). FIG. 17B illustrates relationship between WSA and current for VDD bump (2,0). More specifically, FIG. 17 has WSA vs. current plots for two bumps. FIG. 17A is related to VSS bump in location (2,4), and 17B is related to VDD hump in (2,0). The data points almost form linear lines for both two bumps. The data points indicate that power bump WSA can be used as an alternative to real bump current during test power analysis. The disclosed method can be used to identify high peak bump current for test patterns, eliminating the need of using other power analysis tools or methodologies in evaluating peak current.

TABLE III
WSA AND CURRENT CORRELATION
FOR EACH POWER BUMP

| Power | Power | Coordinates | Data | WSA and I |
|---|---|---|---|---|
| Bump | Type | in Partition | Points | Correlation |
| 1 | VSS | (2, 4) | 2900 | 0.98 |
| 2 | VSS | (4, 4) | 2900 | 0.98 |
| 3 | VSS | (6, 4) | 2900 | 0.98 |
| 4 | VSS | (8, 4) | 2900 | 0.98 |
| 5 | VSS | (10, 4) | 2900 | 0.99 |
| 6 | VDD | (2, 0) | 2900 | 0.98 |
| 7 | VDD | (4, 0) | 2900 | 0.98 |
| 8 | VDD | (6, 0) | 2900 | 0.97 |
| 9 | VDD | (8, 0) | 2900 | 0.98 |
| 10 | VDD | (10, 0) | 2900 | 0.98 |
| 11 | VDD | (2, 7) | 2900 | 0.98 |
| 12 | VDD | (4, 7) | 2900 | 0.98 |
| 13 | VDD | (6, 7) | 2900 | 0.98 |
| 14 | VDD | (8, 7) | 2900 | 0.98 |
| 15 | VDD | (10, 7) | 2900 | 0.98 |

Current Estimation

The current (I) estimation can be described as performing a linear Mean Square (MS) estimation of random variable I by WSA using the function shown in Equation (11), while achieving a minimum estimation error e=eₘ. Applying the probability and estimation theory, when the scaling factor A and offset B are set values in Equation (12), e is minimum. Note that, r is the correlation coefficient between WSA and I, u is standard deviation of each variable, and rJ is the expected value, i.e. mean of the variable.

$$\begin{matrix}e = E \{ {[ 1 - ( A * wsa + B ) ]}^{2} \} \\ e = {e}_{m} & ( 11 ) \\ A = \frac{r {σ}_{f}}{{σ}_{wsa}} , B = {η}_{I} - A {η}_{wsa} \\ {e}_{m} = {σ}_{I}^{2} ( 1 - {r}^{2} ) & ( 12 )\end{matrix}$$

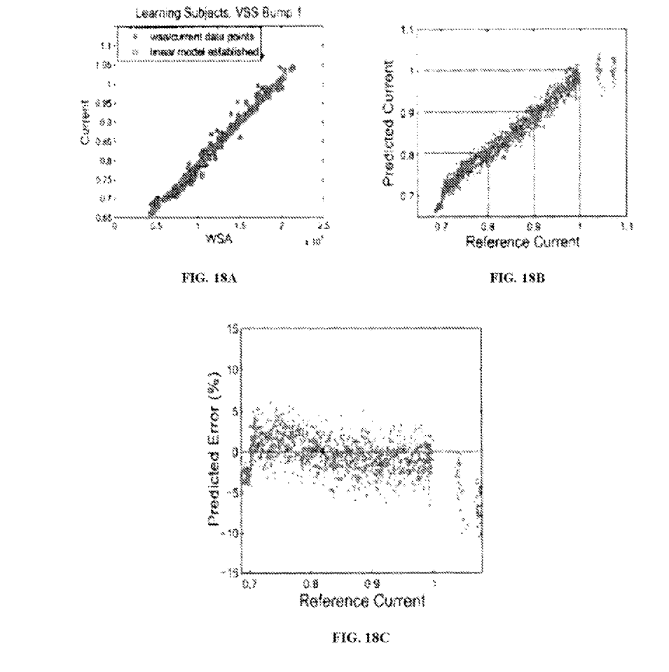

FIG. 18 shows estimation steps and results for VSS bump (2,0). Firstly, 10% of all shift data points are randomly selected to build the linear model in Equation (7). The scaling factor A and offset B are calculated as Equation (8). FIG. 18A illustrates current estimation for VSS bump (2,0). FIG. 18B illustrates a comparison between predicted I and reference I values. FIG. 18C illustrates predicted error of current estimation for VSS bump (2,0). The linear model is plotted as a straight line in FIG. 18A. Secondly, I values for the remaining 90% data points are estimated. A comparison between predicted I and reference I values is shown in FIG. 18B. It forms a line with 45 degree slope across the coordinates origin. The estimation error for all 90% data points is shown in FIG. 18C. Most errors are within 5%, except for some outliers when current is over 1 A. This is the same peak current saturation phenomenon mentioned in Subsection V-A.

The high correlation between bump WSA and current makes it possible to estimate the current using the bump WSA. This is useful if a real power bump current value is needed, for example, when power safety needs to be guaranteed during wafer test, and current supplied by power probes connecting to bumps must be under a limit specified in unit ampere. A small set of learning data establishes a estimation model for current. Using it, the real current values for all power bumps during entire test session can be estimated.

While the methods and systems have been described in connection with preferred embodiments and specific examples, it is not intended that the scope be limited to the particular embodiments set forth, as the embodiments herein are intended in all respects to be illustrative rather than restrictive.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

Throughout this application, various publications are referenced. The disclosures of these publications in their entireties are hereby incorporated by reference into this application in order to more fully describe the state of the art to which the methods and systems pertain.

It will be apparent to those skilled in the art that various modifications and variations can be made without departing from the scope or spirit. Other embodiments will be apparent to those skilled in the art from consideration of the specification and practice disclosed herein. It is intended that the specification and examples be considered as exemplary only, with a true scope and spirit being indicated by the following claims.

### REFERENCES

[1] K. Usami and M. Horowitz, Clustered voltage scaling techniques for low-power Design, in Proc. the 1995 International Symposium on Low Power Design (ISLPED '95), pp. 3-8, 1995
[2] W. Zhao, J. Ma, M. Tchranipoor and S. Chakravarty, “Power-Safe Application of Transition Delay Fault Patterns Considering Current Limit during Wafer Test”, in IEEE Asia Test Symposium (ATS '10), 2010

What is claimed is:

1. A method comprising:
creating a test pattern from topology data of an integrated circuit;
creating a map from the topology data of the integrated circuit; and
performing a test power analysis of the integrated circuit using the created test pattern and the map.

2. The method of claim 1, wherein the topology data comprises a Verilog description.

3. The method of claim 1, wherein the map is generated using a parser.

4. The method of claim 1, wherein performing a test power analysis comprises generating a dynamic weighted switching activity (WSA) current matrix from the created test pattern and the created map.

5. The method of claim 4, wherein the dynamic weighted switching activity (WSA) current matrix is generated using a simulator.

6. The method of claim 4, wherein the dynamic weighted switching activity (WSA) current matrix comprises a plurality of regional WSA current matrices.

7. The method of claim 1, wherein the test pattern comprises one or more of stuck-at pattern, bridging-fault pattern, transition-delay pattern, path-delay pattern.

8. The method of claim 1, wherein the topology data comprises die area, cell locations, voltage drain drain (VDD) domains, voltage source source (VSS) domains, power delivery network (PDN) structure.

9. The method of claim 1, wherein performing a test power analysis further comprises:
obtaining package data of the integrated circuit; and
generating a resistance matrix from the topology data and the package data.

10. The method of claim 9, wherein the package data comprises wire bond package data and flip chip package data.

11. The method of claim 1, wherein a test power analysis comprises one or more of: switching activity analysis, average power analysis, regional power analysis, peak current data analysis, current distribution analysis.

12. The method of claim 11, wherein performing the average power analysis comprises using power data from a standard cell library.

13. A method comprising:
obtaining transition information via monitoring transitions of a plurality of test cycles in a test session of an integrated circuit;
obtaining simulation data via simulating a plurality of functions of the plurality of test cycles in the test session of the integrated circuit using the transition information; and
performing a test power analysis of the plurality of test cycles in the test session of the integrated circuit using the obtained simulation data.

14. The method of claim 13, wherein monitoring transitions of a plurality of test cycles in a test session and simulating a plurality of functions of the plurality of test cycles in the test session occur simultaneously.

15. The method of claim 13, wherein the plurality of test cycles comprise one or more shift cycles, one or more capture cycles, or combination thereof.

16. The method of claim 13, wherein the simulation data are obtained via a verilog procedural interface (VPI).

17. The method of claim 13, wherein the transition information comprises switching cell type, loading capacitance, transition time.

18. The method of claim 13, wherein the simulation data comprises one or more of start time of a test cycle, end time of a test cycle, type of a test cycle, relation of a specific transition and a specific test cycle, fan-out gates, and parasitic wire capacitance at a transition site.

19. The method of claim 13, wherein performing a test power analysis comprises translating simulation data to weighted switching activity (WSA) and power value.

20. The method of claim 13, wherein the power value comprises power leakage value, internal power value and switching power value.
